(19) United States
(12) Patent Application Publication
(10) Pub. No.: US 2025/0248157 A1
(43) Pub. Date: Jul. 31, 2025

(54) IMAGE SENSOR AND METHOD FOR FABRICATING THE SAME

(71) Applicant: Samsung Electronics Co., Ltd., Suwon-si (KR)

(72) Inventor: Mintae CHUNG, Suwon-si (KR)

(73) Assignee: Samsung Electronics Co., Ltd., Suwon-si (KR)

(21) Appl. No.: 18/820,394

(22) Filed: Aug. 30, 2024

(30) Foreign Application Priority Data
Jan. 25, 2024 (KR) 10-2024-0011290

(51) Int. Cl. H01L 27/146

(52) U.S. Cl. CPC H10F 39/8063; H10F 39/024; H10F 39/182; H10F 39/8053

(57) ABSTRACT

An image sensor that includes a substrate region including first and second pixel regions; and a microlens array layer on the substrate region and including a first microlens and a second microlens respectively corresponding to the first and second pixel regions. The first pixel region and the second pixel region are respectively adjacent to a center and an edge of the microlens array layer. The first microlens is offset from the first pixel region and has a first inclination. The second microlens is offset from the second pixel region and has a second inclination greater than the first inclination. A degree to which the first and second microlenses are offset from the first and second pixel regions, and the first and second inclinations are based on an incident angle of incident light to the first and second microlenses.

### CROSS-REFERENCE TO RELATED APPLICATIONS

The application claims benefit of priority under 35 U.S.C. § 119 to Korean Patent Application No. 10-2024-0011290, filed on Jan. 25, 2024, in the Korean Intellectual Property Office, the disclosure of which is incorporated by reference herein in their entireties.

### BACKGROUND

The present disclosure relates generally to image sensors and methods of manufacturing image sensors.

Image sensors are devices that convert optical image signals into electrical signals, and include charge coupled device (CCD) image sensors and complementary metal oxide semiconductor (CMOS) image sensors. Image sensors include a plurality of pixels. Each pixel includes a light-receiving region that receives incident light and converts it into an electrical signal, and a pixel circuit that outputs a pixel signal using charges generated in the light-receiving region.

Incident light incident on the image sensor may have different incident angles depending on the location of the image sensor. Due to differences in incident angles, incident light may not be focused on a required location within each pixel. Accordingly, the image sensor may not have required photoelectric conversion efficiency.

### SUMMARY

Some example embodiments of the inventive concepts provide an image sensor with improved photoelectric conversion efficiency.

Some example embodiments of the inventive concepts provide a method for fabricating an image sensor with improved photoelectric conversion efficiency.

Some example embodiments of the inventive concepts provide an image sensor that includes a substrate region including a first pixel region and a second pixel region; and a microlens array layer on the substrate region, the microlens array including a first microlens and a second microlens respectively corresponding to the first pixel region and the second pixel region. The first pixel region and the second pixel region are respectively adjacent to a center and an edge of the microlens array layer. The first microlens is offset from the first pixel region and has a first inclination. The second microlens is offset from the second pixel region and has a second inclination greater than the first inclination. A degree to which the first and second microlenses are offset from the first and second pixel regions, and the first and second inclinations, are determined based on an incident angle of incident light to the first and second microlenses.

Some example embodiments of the inventive concepts further provide a method for manufacturing an image sensor that includes forming a first preliminary lens layer on a substrate region including a plurality of pixel regions; forming a first sacrificial layer on the first preliminary lens layer, the first sacrificial layer having a thickness that decreases toward an edge of the first sacrificial layer; forming a second preliminary lens layer by performing an etch-back process on the first sacrificial layer and the first preliminary lens layer, the second preliminary lens layer having a thickness that decreases toward an edge of the second preliminary lens layer; forming a plurality of first preliminary sacrificial patterns on the second preliminary lens layer; forming a second sacrificial layer by performing a reflow process on the plurality of first preliminary sacrificial patterns; and forming a microlens array layer by performing an etch-back process on the second sacrificial layer and the second preliminary lens layer. From a planar view, the plurality of first preliminary sacrificial patterns are offset from the plurality of pixel regions immediately adjacent thereto.

Some example embodiments of the inventive concepts still further provide an image sensor that includes a substrate region including a plurality of pixel regions; and a microlens array layer on the substrate region, the microlens array layer including a plurality of microlenses corresponding to the plurality of pixel regions, and the microlens array layer including a supporting portion between the plurality of microlenses and the substrate region. A top surface of the supporting portion has an inclination that increases from a center to an edge of the microlens array layer. The plurality of microlenses are arranged along the top surface of the supporting portion and are offset from the plurality of pixel regions corresponding thereto based on an incidence angle of incident light to the plurality of microlenses.

Additional aspects will be set forth in part in the description which follows and, in part, will be apparent from the description, or may be learned by practice of some example embodiments of the inventive concepts.

### BRIEF DESCRIPTION OF DRAWINGS

The above and other aspects, features, and advantages of some example embodiments of the present disclosure will be more apparent from the following description taken in conjunction with the accompanying drawings, in which:

FIG. 1 is a block diagram of an image sensor according to some example embodiments.

FIG. 2 is a plan view of the pixel array of FIG. 1.

FIG. 3 is an equivalent circuit diagram of the pixel group of FIG. 1.

FIG. 4 is a cross-sectional view showing an image sensor according to some example embodiments.

FIG. 5 is a diagram showing incident light IL entering the image sensor of FIG. 4.

FIGS. 6, 7A, 8, 9, 10, 11, 12, 13, and 14 are cross-sectional views for explaining a method of manufacturing an image sensor according to some example embodiments.

FIG. 7B is a plan view showing the preliminary sacrificial patterns of FIG. 7A.

FIG. 15 is a cross-sectional view showing an image sensor according to some example embodiments.

FIG. 16 is a cross-sectional view showing an image sensor according to an embodiment.

FIG. 17 is a cross-sectional view showing an image sensor according to some example embodiments.

FIG. 18 is a cross-sectional view showing an image sensor according to some example embodiments.

FIG. 19 is a plan view showing the color filter layer 40 according to some example embodiments.

FIG. 20 is a cross-sectional view of an image sensor PA6 along line A-A′ of FIG. 19.

### DETAILED DESCRIPTION

Hereinafter, some example embodiments are described in detail with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are some example embodiments, and thus, the present disclosure is not limited thereto, and may be realized in various other forms. Some example embodiments provided in the following description is not excluded from being associated with one or more features of some other example embodiments also provided herein or not provided herein but consistent with the present disclosure. It will be also understood that, even if a certain step or operation of manufacturing an apparatus or structure is described later than another step or operation, the step or operation may be performed later than the other step or operation unless the other step or operation is described as being performed after the step or operation.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

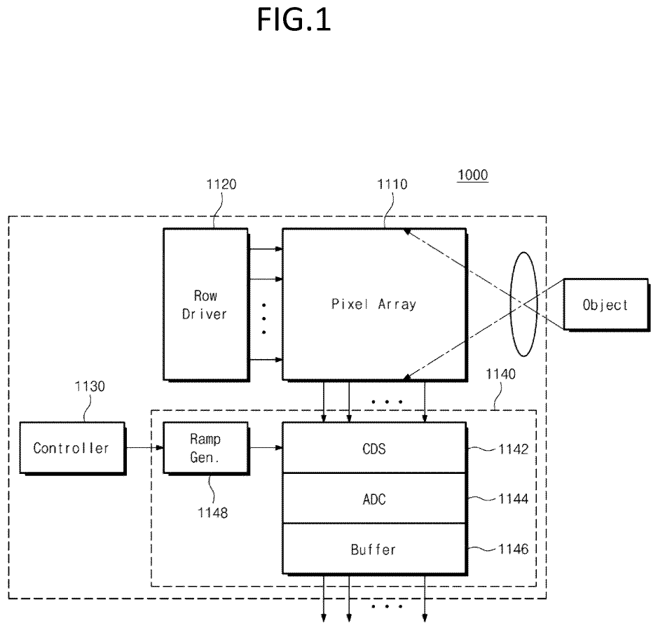

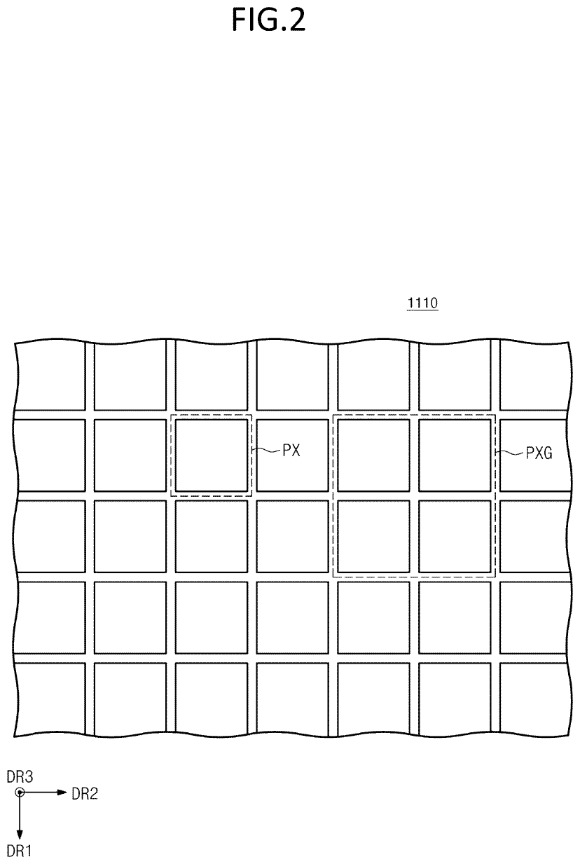

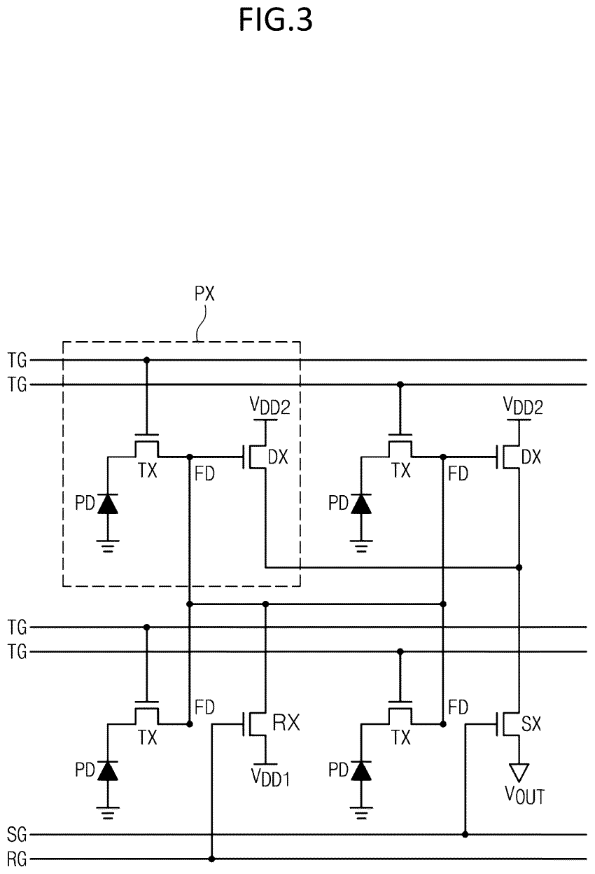

FIG. 1 is a block diagram of an image sensor according to some example embodiments. FIG. 2 is a plan view of a pixel array of FIG. 1. FIG. 3 is an equivalent circuit diagram of a pixel group of FIG. 1.

Referring to FIG. 1, an image sensor 1000 may be provided. The image sensor 1000 may be mounted in an electronic device having an image or light sensing function. For example, the electronic device may be a camera, a smartphone, a wearable device, the Internet of Things (IoT), a tablet PC (Personal Computer), a PDA (Personal Digital Assistant), a PMP (portable multimedia player), or a navigation device. The image sensor 1000 may be mounted in electronic devices provided as components in various devices (e.g., vehicles, furniture, manufacturing facilities, doors, various measuring devices, etc.).

The image sensor 1000 may include a control unit including a pixel array 1110, a controller 1130, a row driver 1120, and a pixel signal processor 1140.

As shown in FIG. 2, the pixel array 1110 may include a plurality of pixels two-dimensionally arranged along a first direction DR1 and a second direction DR2. The plurality of pixels may be arranged in a regular pattern to generate a high-quality image. For example, the plurality of pixels may be arranged in a Bayer pattern or a chess mosaic pattern. When the plurality of pixels have a Bayer pattern, the pixels in the pixel array 1110 may receive red light, green light, and blue light, respectively. In some example embodiments, the plurality of pixels may receive cyan light, magenta light, and yellow light. Each of the pixels may include a photoelectric conversion device. The photoelectric conversion device may absorb light to generate charge carriers (electrons or holes). For example, the photoelectric conversion device may include photodiodes, phototransistors, photogates, pinned photodiodes, or a combination thereof. Output voltages of the plurality of pixels may be determined based on the generated charge carriers.

The pixel array 1110 may include a pixel group PXG. The pixel group PXG may be a set of pixels PX sharing a reset transistor RX, a selection transistor SX, and a source follower transistor DX. Although the pixel group PXG is illustrated as being composed of four pixels PX, in some example embodiments the pixel group PXG may include less than or more than four pixels PX.

The pixel array 1110 may be driven by receiving a plurality of driving signals, such as a row selection signal, a reset signal, and a charge transfer signal, from the row driver 1120. The row driver 1120 may provide a plurality of driving signals to the pixel array 1110 for driving the plurality of pixels. In some example embodiments, the driving signals may be provided for each row of the pixel array 1110. Pixels belonging to one row of the pixel array 1110 selected by the driving signals of the row driver 1120 may be simultaneously activated by a signal output from the row driver 1120. The pixels belonging to the selected row may provide output voltages according to absorbed light to output lines of corresponding columns. In some example embodiments, the pixels belonging to the selected one row may provide the output voltages together. The output voltages may be provided to correlated double sampler 1142.

The pixel signal processor 1140 may include a correlated double sampler (CDS) 1142, an analog-to-digital converter (ADC) 1144, and a buffer 1146. The correlated double sampler 1142 may sample and hold the output voltages provided by the pixel array 1110. The correlated double sampler 1142 can reduce noise and improve Signal Noise Ratio (SNR). The correlated double sampler 1142 can be configured to remove noise voltages from the output voltages of the pixel. For example, the correlated double sampler 1142 may double sample a specific noise level and a signal level by an output signal, and output a difference level corresponding to a difference between the noise level and the signal level. The correlated double sampler 1142 may output a result based on ramp signals generated by a ramp signal generator 1148.

The analog-to-digital converter 1144 may convert an analog signal corresponding to the difference level received from the correlated double sampler 1142 into a digital signal. The buffer 1146 may latch digital signals, and the latched signals may be sequentially output to the outside of the image sensor 1000 and transferred to an image processor (not shown).

The controller 1130 may control the row driver 1120 so that the pixel array 1110 absorbs light to accumulate charge carriers, temporarily stores the accumulated charge, and outputs an electrical signal according to the accumulated charge to the outside of the pixel array 1110. Also, the controller 1130 may control the pixel signal processor 1140 to measure an output voltage provided by the pixel array 1110.

Referring to FIG. 3, each of the plurality of pixels PX may include a photoelectric conversion device PD, a transfer transistor TX, and a floating diffusion region FD. The photoelectric conversion device PD may generate and accumulate photo charges in proportion to the amount of light incident from the outside, and may include a photodiode, a phototransistor, a photogate, a pinned photodiode, or a combination thereof.

The transfer transistor TX may include a transfer gate TG. The transfer gate TG may transfer charge carriers generated by the photoelectric conversion device PD to the floating diffusion region FD. A transfer control voltage provided from the row driver 1120 may be applied to the transfer gate TG. For example, a channel may be formed between the photoelectric conversion device PD and the floating diffusion region FD by the transfer control voltage applied to the transfer gate TG. Charge carriers generated by the photoelectric conversion device PD may move to the floating diffusion region FD along the channel between the photoelectric conversion device PD and the floating diffusion region FD. A drain terminal of the transfer transistor TX may be electrically connected to the floating diffusion region FD, and a source terminal of the transfer transistor TX may be electrically connected to the photoelectric conversion device PD.

The floating diffusion region FD may receive, accumulate, and store charges generated by the photoelectric conversion device PD. The source follower transistor DX may be controlled according to the amount of charge accumulated in the floating diffusion region FD. A gate terminal of the source follower transistor DX may be electrically connected to the floating diffusion region FD. A second power voltage VDD2 may be applied to a drain terminal of the source follower transistor DX. A source terminal of the source follower transistor DX may be electrically connected to a drain terminal of the selection transistor SX. The source follower transistor DX may be a source follower buffer amplifier that outputs a current proportional to the amount of charge accumulated in the floating diffusion region FD.

The reset transistor RX may periodically reset charges accumulated in the floating diffusion region FD. A gate terminal of the reset transistor RX may be electrically connected to a reset signal line RG. A drain terminal of the reset transistor RX may be connected to the floating diffusion region FD. A first power voltage VDD1 may be applied to a source terminal of the reset transistor RX. In some example embodiments, the first power voltage VDD1 may be substantially equal to the second power voltage VDD2. When the reset transistor RX is turned on, the first power voltage VDD1 applied to the source terminal of the reset transistor RX is transferred to the floating diffusion region FD. When the reset transistor RX is turned on, charges accumulated in the floating diffusion region FD are discharged to reset the floating diffusion region FD. When electrons are charge carriers, the voltage of the floating diffusion region FD may decrease as electrons are accumulated in the floating diffusion region FD. When the reset transistor RX is turned on, electrons of the floating diffusion region FD are discharged to the outside, and the voltage of the floating diffusion region FD may increase to the first power voltage VDD1. As the first power voltage VDD1 is applied to the floating diffusion region FD, the first power voltage VDD1 may be applied to the gate terminal of the source follower transistor DX to reset the output of the source follower transistor DX.

The selection transistor SX may select a plurality of pixels PX in each row. The selection transistor SX may transfer current generated by the source follower transistor DX included in each of the selected pixels to an output line (not shown). A drain terminal, a source terminal, and a gate terminal of the selection transistor SX may be electrically connected to the source terminal, the output line, and the row selection line SG of the source follower transistor DX, respectively. A selection control signal applied from the row selection line SG may be applied to the gate terminal of the selection transistor SX to output a signal generated by the source follower transistor DX to the output line.

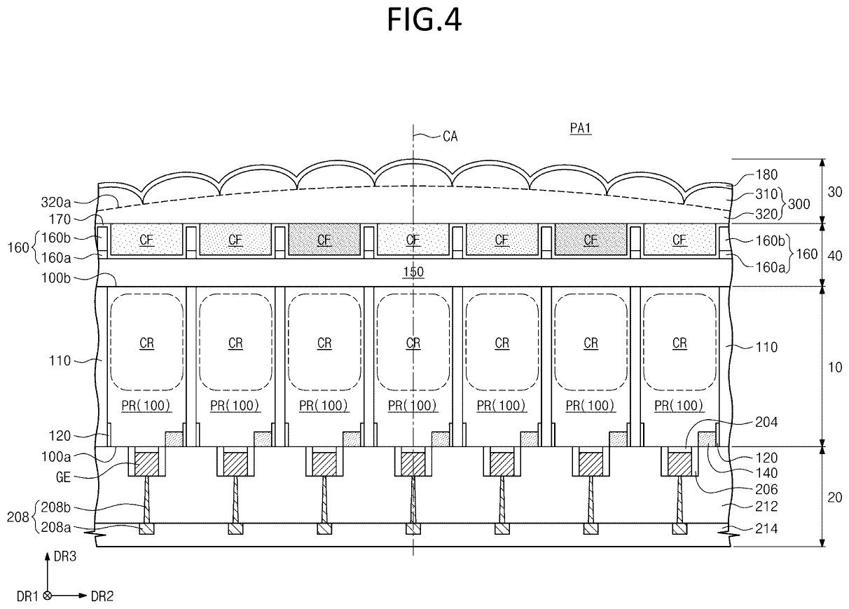

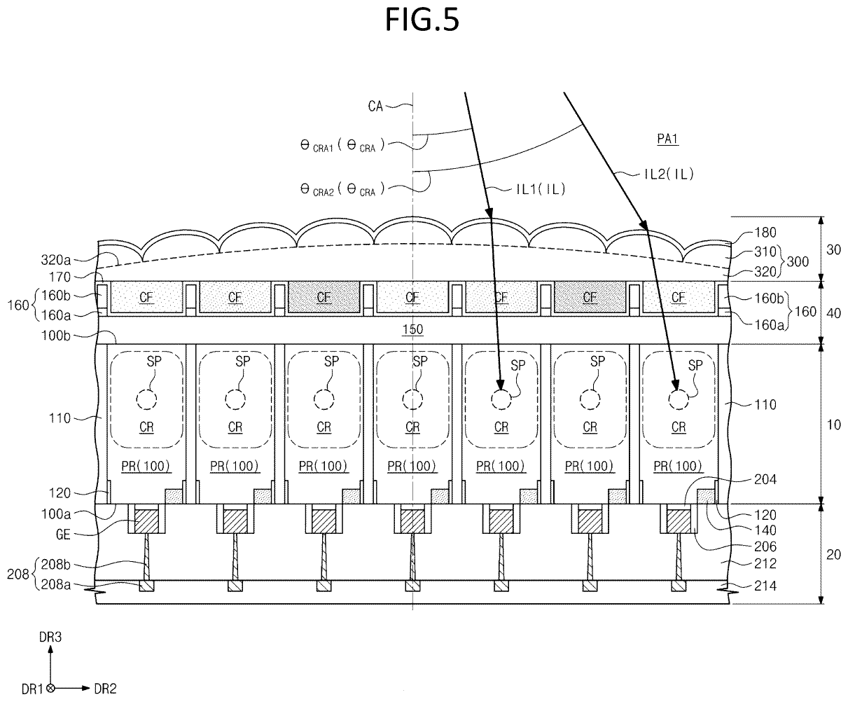

FIG. 4 is a cross-sectional view showing an image sensor according to embodiments. FIG. 5 is a diagram showing incident light IL entering the image sensor of FIG. 4.

Referring to FIG. 4, an image sensor PA1 may be provided including a device layer 10, a wiring layer 20, an optical element layer 30, and a color filter layer 40. The wiring layer 20 and the optical element layer 30 may be spaced apart from each other with the device layer 10 interposed therebetween. The color filter layer 40 may be provided between the device layer 10 and the optical element layer 30. The device layer 10 may include a substrate region 100. the substrate region 100 may include a semiconductor material. For example, the substrate region 100 may include silicon (Si), germanium (Ge), or silicon-germanium (SiGe). The substrate region 100, for example, may refer to a region of the semiconductor substrate region 100 surrounded by a pixel isolation layer 110 and a device isolation layer 120, which will be described later. The substrate region 100 may include a front side 100a and a back side 100b facing opposite directions. As shown in FIG. 5, incident light IL may be incident on the back side 100b of the substrate region 100. The front side 100a and the back side 100b may extend along the first direction DR1 and the second direction DR2. The front side 100a and the back side 100b may be spaced apart from each other along the third direction DR3. The third direction DR3 may be the direction from the front side 100a to the back side 100b. For example, the third direction DR3 may be perpendicular to the first direction DR1 and the second direction DR2.

The substrate region 100 may have a first conductivity type. For example, the first conductivity type may be p-type or n-type. When the conductivity type of the substrate region 100 is p-type, the substrate region 100 may be the silicon (Si) substrate region 100 containing a group 3 element (e.g., boron (B), aluminum (Al), gallium (Ga), indium (In), etc.) or a group 2 element as an impurity. When the conductivity type of the substrate region 100 is n-type, the substrate region 100 may be a silicon (Si) substrate region 100 containing a group 5 element (e.g., phosphorus (P), arsenic (As), antimony (Sb), etc.), a group 6 element, or a group 7 element as an impurity. Hereinafter, impurities that cause the substrate region 100 to have the first conductivity type and a second conductivity type may be referred to as first impurities and second impurities, respectively. The first impurity may have a conductivity type opposite to that of the second impurity. When the first conductivity type is p-type or n-type, the second conductivity type may be n-type or p-type, respectively. The substrate region 100 may be an epitaxial layer formed through an epitaxial growth process. For example, an epitaxial layer may be formed in the lower part of the substrate region 100 by an epitaxial growth process (e.g., molecular beam epitaxy (MBE), pulsed laser deposition (PLD), physical vapor deposition (PVD), chemical vapor deposition (CVD), or atomic layer deposition (ALD). For brevity of explanation, hereinafter the first conductivity type is described as p-type, and the second conductivity type is described as n-type.

The device layer 10 may include the pixel isolation layer 110. The pixel isolation layer 110 may be provided within the substrate region 100. The pixel isolation layer 110 may define pixel regions PR. Each of the pixel regions PR may be a portion of the substrate region 100. For brevity of explanation, seven pixel regions PR are shown. The number of pixel regions PR may be determined as needed. The pixel isolation layer 110 may be provided between the pixel regions PR. From a planar view, the pixel isolation layer 110 may surround each pixel region PR. The pixel isolation layer 110 may extend along the third direction DR3. For example, the pixel isolation layer 110 may be a deep trench isolation (DTI) layer. In some example embodiments, the top and bottom surfaces of the pixel isolation layer 110 may be located at substantially the same level as the back side 100b and the front side 100a, respectively.

The pixel isolation layer 110 may have a smaller refractive index than the substrate region 100. The pixel isolation layer 110 can prevent or reduce the electrical crosstalk phenomenon that lowers the signal-to-noise ratio by exchanging charge carriers between adjacent pixel regions PR. For example, the pixel isolation layer 110 may include a conductive material (e.g., at least one of doped polysilicon, metal, metal silicide, metal nitride, or a metal-containing material), an insulating material (e.g., a silicon-based insulating material (e.g., silicon nitride (SiₓN_{y}), silicon oxide (SiOₓ), and/or silicon oxynitride (SiNₓO_{y})), or a high-k dielectric material (e.g., metal oxides containing at least one metal selected from the group consisting of hafnium (Hf), zirconium (Zr), aluminum (Al), tantalum (Ta), titanium (Ti), yttrium (Y), and lanthanoid (La)). In some example embodiments, a sidewall of the pixel isolation layer 110 is doped with a highly reflective material, thereby preventing or reducing the optical crosstalk phenomenon in which light is detected not in the pixel on which light is incident, but in the pixel adjacent to it. For example, the highly reflective material may be boron (B). When the pixel isolation layer 110 includes the conductive material, in one example, a negative fixed charge layer is provided between the pixel isolation layer 110 and the substrate region 100. The negative fixed charge layer may contain, for example, a metal oxide containing at least one metal selected from the group consisting of hafnium (Hf), zirconium (Zr), aluminum (Al), tantalum (Ta), titanium (Ti), yttrium (Y), and lanthanoid (La). However, the structure of the pixel isolation layer 110 may be determined as needed. In some example embodiments, the pixel isolation layer 110 may be an insulating layer having a single-layer structure.

The device layer 10 may include the device isolation layers 120. The device isolation layers 120 may be provided adjacent to the front side 100a. The device isolation layers 120 may define active regions. The active regions may be regions provided with gate electrodes GE and floating diffusion regions 140, which will be described later. Bottom surfaces of the device isolation layers 120 may be located at substantially the same level as the front side 100a. The device isolation layers 120 may contact the pixel isolation layers 110 that are immediately adjacent to each other. The thicknesses of the device isolation layers 120 may be smaller than the thickness of the pixel isolation layer 110. The thicknesses of the device isolation layers 120 may be the sizes of the device isolation layers 120 along the third direction DR3. From a planar view, the device isolation layers 120 may surround the active regions. For example, the device isolation layers 120 may be shallow trench isolation (STI) layers. The device isolation layers 120 may include a silicon-based insulating material. For example, the device isolation layers 120 may include silicon nitride (SiₓN_{y}), silicon oxide (SiOₓ), silicon oxynitride (SiNₓO_{y}), or a combination thereof.

Photoelectric conversion regions CR may be provided in each of the pixel regions PR. In some example embodiments, the photoelectric conversion regions CR may be disposed adjacent to the back side 100b. In some example embodiments, the photoelectric conversion regions CR may be photodiodes including a first impurity region and a second impurity region. For example, the photoelectric conversion regions CR may include p-n photodiodes. In some example embodiments, p-type regions of the photoelectric conversion regions CR may be the substrate region 100, and n-type regions may be formed by implanting the second impurity into the substrate region 100. In some example embodiments, the p-type regions may be formed by implanting the first impurity into the substrate region 100. In some example embodiments, the doping concentration of the p-type regions may be higher than the doping concentration of the substrate region 100. The p-type and the n-type regions may have a potential gradient due to the p-n junction structure. In some example embodiments the photoelectric conversion regions CR include photodiodes. In some example embodiments, the photoelectric conversion regions CR may include phototransistors, photogates, or pinned photodiodes.

When light is incident on the photoelectric conversion regions CR, electron-hole pairs (EHP) may be generated in the photoelectric conversion regions CR. For example, electron-hole pairs can be generated in a depletion region formed in a region adjacent to a p-n junction. The stronger the intensity of light incident on the photoelectric conversion region CR, the more electron-hole pairs can be generated. The photoelectric conversion region CR may have a sweet spot SP, which is a region with relatively high photoelectric conversion efficiency. When incident light IL incident on the photoelectric conversion regions CR is focused on the sweet spot SP, a relatively large number of electron-hole pairs may be generated. For example, the sweet spot SP may be a region with maximum photoelectric conversion efficiency within the photoelectric conversion region CR. In some example embodiments, when the incident light IL incident on the photoelectric conversion regions CR is focused on the sweet spot SP (or when the focus area of the incident light IL, which will be described later, matches the sweet spot SP), photoelectric conversion efficiency (or generation efficiency of electron-hole pairs) may be maximum. The photoelectric conversion regions CR may be formed through substantially the same process. Accordingly, the photoelectric conversion regions CR may have the sweet spots SP at substantially the same location. For example, the sweet spots SP may be located at substantially the same depth from the back side 100b and may be located at the centers of the corresponding photoelectric conversion regions CR from a planar view. When a reverse bias is applied to the photoelectric conversion regions CR, charge carriers (electrons or holes) may be accumulated in the photoelectric conversion regions CR. Charge carriers accumulated in the photoelectric conversion regions CR may transfer to the floating diffusion regions 140, which will be described later, by a voltage applied to the gate electrodes GE, which will be described later. The photoelectric conversion regions CR may be spaced apart from the floating diffusion regions 140.

The device layer 10 may include the floating diffusion regions 140. The floating diffusion regions 140 may be provided within the substrate region 100. The floating diffusion regions 140 may be provided in each of the pixel regions PR. The floating diffusion regions 140 may be disposed on one side of the gate electrodes GE. The floating diffusion regions 140 may be disposed adjacent to the front side 100a. The floating diffusion regions 140 may have the second conductivity type. In some example embodiments, the floating diffusion regions 140 may be formed by injecting the second impurity into the substrate region 100. The floating diffusion regions 140 may be spaced apart from the photoelectric conversion regions CR. The region between the floating diffusion regions 140 and the photoelectric conversion regions CR (that is, some region of the substrate region 100) may have the first conductivity type. The floating diffusion regions 140 may receive and accumulate charge carriers provided from the photoelectric conversion regions CR. The floating diffusion regions 140 may function as a drain of a transfer transistor (TX in FIG. 3). The floating diffusion region 140 may function as a source of a reset transistor (RX in FIG. 3). The floating diffusion region 140 may be electrically connected to the source follower gate of the source follower transistor (DX in FIG. 3). The source follower transistor (DX in FIG. 3) is connected to the select transistor (SX in FIG. 3).

The device layer 10 may include the gate electrodes GE. The gate electrodes GE may be provided on the front side 100a. The gate electrodes GE may function as gate electrodes of different transfer transistors TX. The gate electrodes GE may include an electrically conductive material. For example, the gate electrodes GE may include polysilicon (e.g., doped polysilicon), metal silicide, or metal (e.g., copper (Cu), aluminum (Al), molybdenum (Mo), platinum (Pt), titanium (Ti), tantalum (Ta), tungsten (W), or a combination thereof).

The device layer 10 may include gate insulating layers 204. The gate insulating layers 204 may be provided between the gate electrodes GE and the front side 100a. In some example embodiments, the gate insulating layers 204 may extend along the surfaces of the gate electrodes GE facing the front side 100a to electrically separate the gate electrodes GE from the substrate region 100. For example, the gate insulating layers 204 may include the silicon-based insulating material (e.g., silicon nitride (SiₓN_{y}), silicon oxide (SiOₓ), and/or silicon oxynitride (SiNₓO_{y})) or a high-k dielectric material (e.g., metal oxides containing at least one metal selected from the group consisting of hafnium (Hf), zirconium (Zr), aluminum (Al), tantalum (Ta), titanium (Ti), yttrium (Y), and lanthanoid (La)).

The device layer 10 may include gate spacers 206. The gate spacers 206 may be provided on sidewalls of the gate electrodes GE. In some example embodiments, the gate spacers 206 may be configured to electrically isolate the gate electrodes GE from other components. For example, the gate spacers 206 may include silicon nitride (SiₓN_{y}), silicon carbide nitride (SiCₓN_{y}), or silicon oxynitride (SiNₓO_{y}).

The wiring layer 20 may include a first wire insulating layer 212 and a second wire insulating layer 214. The first wire insulating layer 212 and the second wire insulating layer 214 may be provided sequentially on the front side 100a. The first wire insulating layer 212 may be provided on the front side 100a of the substrate region 100 to cover the gate electrodes GE. The second wire insulating layer 214 may be provided on the first wire insulating layer 212. The first and the second wire insulating layers 212 and 214 may include an electrical insulating material. The first and the second wiring insulating layers 212 and 214 may include, for example, the silicon-based insulating material such as silicon nitride (SiₓN_{y}), silicon oxide (SiOₓ), and/or silicon oxynitride (SiNₓO_{y}). Two insulating layers (e.g. the first and the second wire insulating layers 212 and 214) provided on the front side 100a are shown, but this is an example. In some example embodiments, three or more insulating layers may be provided on the front side 100a.

The wiring layer 20 may include wires 208. The wires 208 may be provided within the first and the second wire insulating layers 212 and 214. The wires 208 may include horizontal wires 208a and vertical wires 208b. The horizontal wires 208a may extend along the direction parallel to the front side 100a (e.g., in the first direction DR1, the second direction DR2, or the direction of combination of the first direction DR1 and the second direction DR2). The vertical wires 208b may extend along the direction perpendicular to the front side 100a (e.g., the third direction DR3). The shown wires 208 are examples. The wires 208 may be appropriately selected as needed. For example, the horizontal wires 208a and the vertical wires 208b may be used to form electrical connections between each of the gate electrodes GE and other components. The wires 208 may output electrical signals generated in the pixel regions PR to the outside. Although not shown, the wires 208 may be provided between the floating diffusion regions 140 and other electrical components (e.g., gate electrodes of source follower transistors (DX in FIG. 3)) to provide the electrical connections between the floating diffusion regions 140 and other electrical components. The wires 208 may include the electrically conductive material (e.g., metal). For example, the wires 208 may include titanium (Ti), tungsten (W), molybdenum (Mo), and copper (Cu). The wires 208 may be electrically connected to at least one of a transmission gate, a source follower gate, a reset gate, and a selection gate. For example, the wires 208 may be configured to apply the power supply voltage (VDD) to the drain of the reset transistor RX or the drain of the source follower transistor DX.

The color filter layer 40 may include a bottom insulating layer 150. The bottom insulating layer 150 may be provided on the back side 100b. In some example embodiments, the bottom insulating layer 150 may include a bottom antireflective layer (BARL). The bottom antireflective layer (BARL) may be configured so that incident light IL is not substantially reflected from the back side 100b. For example, the bottom antireflective layer (BARL) may include tantalum (Ta) or tantalum nitride (TaN). The bottom insulating layer 150 may have a single-layer structure or a multi-layer structure.

The color filter layer 40 may include a light blocking pattern 160. The light blocking pattern 160 may be provided on the bottom insulating layer 150. The light blocking pattern 160 may be provided between color filters CF, which will be described later. The light blocking pattern 160 may be configured to optically separate the color filters CF that are immediately adjacent to each other. From a planar view, the light blocking pattern 160 may have a shape corresponding to the pixel isolation layer 110. For example, the light blocking pattern 160 may overlap the pixel isolation layer 110 along the third direction DR3. The light blocking pattern 160 may include a first light blocking pattern 160a and a second light blocking pattern 160b. The first light blocking pattern 160a and the second light blocking pattern 160b may be sequentially stacked on the bottom insulating layer 150. In some example embodiments, the first light blocking pattern 160a may include the electrically conductive material (e.g., metal, metal nitride, or a combination thereof). For example, the first light blocking pattern 160a may include titanium (Ti), titanium nitride (TiN), or a combination thereof. The second light blocking pattern 160b may include a different material from the first light blocking pattern 160a. For example, the second light blocking pattern 160b may include an organic material. In some example embodiments, the second light blocking pattern 160b may include a low-refractive index material having insulating properties. For example, the low-refractive index material may include a polymer containing nanoparticles (e.g., silica). It is an example that the light blocking pattern 160 is composed of the first and the second light blocking patterns 160a and 160b. In some example embodiments, the light blocking pattern 160 may have a single-layer structure or a multi-layer structure of three or more layers.

The color filter layer 40 may include the color filters CF. The color filters CF may be provided on the bottom insulating layer 150. The color filter CF may be configured so that light in a required wavelength bandwidth passes through the color filter CF. Incident light IL passing through the color filters CF may be incident on the pixel regions PR corresponding to the color filters CF. In some example embodiments, from a planar view, the shapes of the color filters CF may be substantially the same as the shapes of the pixel regions PR. The color filters CF may be arranged along the direction parallel to the back side 100b on the bottom insulating layer 150. For example, the color filters CF may be arranged along the first direction DR1 and the second direction DR2. The color filters CF may be composed of the color filters CF that transmit light of different wavelength bandwidth. In some example embodiments, the color filters CF may include red, green, and blue color filters CF. In some example embodiments, the color filters CF may include cyan, magenta, and yellow color filters CF. The color filters CF may be formed by, for example, a dyeing method, a pigment dispersion method, an electrodeposition method, and a printing method.

The color filter layer 40 may include a protective layer 170. The protective layer 170 may be provided between the bottom insulating layer 150 and the color filters CF and between the light blocking patterns 160 and the color filters CF. For example, the protective layer 170 may extend conformally along the surfaces of the light blocking patterns 160 and the bottom insulating layer 150. The protective layer 170 may be configured to protect other components from the external environment. The protective layer 170 may include a high-k dielectric material having insulating properties. For example, the protective layer 170 may include aluminum oxide (AlₓO_{y}) or hafnium oxide (HfₓO_{y}).

The optical element layer 30 may include a microlens array layer 300. The microlens array layer 300 may be provided on the color filters CF. The microlens array layer 300 can focus incident light IL. The microlens array layer 300 may include microlenses 310 and a supporting portion 320. Microlenses 310 may be provided on the supporting portion 320. In some example embodiments, the microlenses 310 and the supporting portion 320 may form a single-structure. For example, the microlenses 310 and the supporting portion 320 may be connected to each other without a boundary therebetween. In some example embodiments, the microlenses 310 and the supporting portion 320 may contact each other with a boundary therebetween.

The supporting portion 320 may be configured to support the microlenses 310. The supporting portion 320 may be located on the color filters CF. The thickness of the supporting portion 320 may decrease from the center to the edge of the substrate region 100. The thickness of the supporting portion 320 may be the size of the supporting portion 320 along the third direction DR3. The center of the substrate region 100 may refer to a region adjacent to a central axis CA of the substrate region 100. The central axis CA of the substrate region 100 extends along the third direction DR3 and may be a virtual axis passing through the center of the substrate region 100. The central axis of the microlens array layer 300 may be aligned with the central axis CA of the substrate region 100. The top surface 320a of the supporting portion 320 may be configured to be inclined. The top surface 320a of the supporting portion 320 may be a virtual surface defined for explanation. The top surface 320a of the supporting portion 320 may be a curved surface that passes through the boundaries of the microlenses 310. Inclination of the top surface 320a of the supporting portion 320 may increase from the center to the edge of the substrate region 100.

Microlenses 310 may be arranged along the top surface 320a of the supporting portion 320. From a planar view, the microlenses 310 may be arranged two-dimensionally, forming rows and columns. For example, the rows may extend along the first direction DR1 and be arranged along the second direction DR2. For example, the columns may extend along the second direction DR2 and be arranged along the first direction DR1.

Incident light IL incident on the microlens array layer 300 may have an incident angle θ_{CRA} depending on the incident position on the microlens array layer 300. The incident angle θ_{CRA} may be the angle between incident light IL and the central axis CA of the substrate region 100. The incident angle θ_{CRA} may be the chief ray angle (CRA). As the incident angle θ_{CRA} is closer to the central axis CA of the substrate region 100, the incident angle θ_{CRA} may be smaller. As the distance from the central axis CA of the substrate region 100 increases, the incident angle θ_{CRA} may increase. Incident light IL having a small incident angle θ_{CRA1} may be incident on the microlens 310 located close to the central axis CA of the substrate region 100. Incident light IL having a large incident angle θ_{CRA2} may be incident on the microlens 310 located far from the central axis CA of the substrate region 100. Incident light IL may pass through the microlenses 310 and be focused on the photoelectric conversion regions CR corresponding to the microlenses 310, respectively.

Unlike the inventive concepts, when the microlens array layer 300 includes general microlenses having the same shape and height but vertically aligned with the corresponding pixel regions PR, the position of the focus area of incident light IL may vary due to differences in an incident angle θ_{CRA} according to the position on the microlens array layer 300. For example, the focus area of incident light IL having a large incident angle θ_{CRA2} is spaced farther from the central axis CA of the substrate region 100 than the focus area of incident light IL having a small incident angle θ_{CRA1}, the focus area of incident light IL having a large incident angle θ_{CRA2} is located adjacent to the microlens array layer 300. Incident light IL having a large incident angle θ_{CRA2} may be focused by a microlens located far from the central axis CA of the substrate region 100. Incident light IL having a small incident angle θ_{CRA1} may be focused by a microlens located close to the central axis CA of the substrate region 100. The focus area of incident light IL having a large incident angle θ_{CRA2} may be shifted horizontally and vertically from the focus area of incident light IL having a small incident angle θ_{CRA1}. For example, the focus area of incident light IL (e.g., IL2) having a large incident angle θ_{CRA2} may be shifted along the second direction DR2 and the third direction DR3 from the focus area of incident light IL (e.g., IL1) having a small incident angle θ_{CRA1}. The degree of shift along the third direction DR3 may be determined by the equation below. The degree of shift along the third direction DR3 may be determined by the distance between the back side 100b and the focus area of incident light IL having a large incident angle θ_{CRA2} and the distance between the back side 100b and the focus area of incident light IL having a small incident angle θ_{CRA1}.

Δh=h₀(1−cos(θ_{CRA2}))−h₀(1−cos(θ_{CRA1}))

=h₀(cos(θ_{CRA1})−cos(θ_{CRA2}))

(Δh: the difference between the distance between the back side 100b and the focus area of incident light IL having a large incident angle θ_{CRA2} and the back side 100b and the focus area of incident light IL having a small incident angle θ_{CRA1} (e.g. degree of shift along the third direction DR3), h₀: the distance between the back side 100b and the focus area of incident light IL with an incident angle θ_{CRA} of 0 degrees (°))

Unlike the inventive concepts, when the microlens array layer 300 includes general microlenses that have the same shape and height but are vertically aligned with the corresponding pixel regions PR, the focus regions may deviate from the corresponding sweet spots SP. For example, the focus area of incident light IL passing through the microlens adjacent to the central axis CA of the substrate region 100 coincides with the corresponding sweet spot SP, but the focus area of incident light IL passing through the microlens adjacent to the edge of the microlens array 300 may deviate from the corresponding sweet spot SP. When the focus area of the incident light IL is out of the sweet spot SP, the required photoelectric conversion efficiency may not be obtained. Accordingly, the quality of images using the image sensor may be deteriorated.

According to some example embodiments of the inventive concepts, the microlenses 310 may be configured to match the focus areas of incident light IL to the sweet spots SP. For example, the inclination, height, and degree of deviation from the pixel regions of the microlenses 310 may be determined (e.g., set) so that the corresponding focus areas and sweet spots SP match each other. As shown in FIG. 5, the first incident light L1 and the second incident light L2 passing through the microlenses 310 adjacent to the center and edge of the microlens array layer 300 may be focused on the corresponding sweet spots SP, respectively. The focus areas and the sweet spots SP may be arranged at substantially the same location within the pixel regions PR. For example, from a planar view, the focus areas and the sweet spots SP may be located in the centers of the corresponding pixel regions PR. For example, the distances between the focus areas and the back side 100b may be substantially equal to the distances between the sweet spots SP and the back side 100b.

The microlenses 310 may be tilted to have inclinations that increase from the center to the edge of the substrate region 100. For example, the angle between the optical axis of the microlens 310 adjacent to the edge of the microlens array layer 300 and the central axis CA of the substrate region 100 may be greater than the angle between the optical axis of the microlens 310 adjacent to the center of the substrate region 100 and the central axis CA of the substrate region 100. From a planar view, the area of the microlenses 310 may become smaller from the center to the edge of the substrate region 100.

The microlenses 310 may be configured to have a height that decreases from the center of the substrate region 100 to the edge. The height of the microlenses 310 may be the distance between the tops of the microlenses 310 and the back side 100b.

The microlenses 310 may be arranged to be offset from the corresponding pixel regions PR. The misalignment of the microlenses 310 and the corresponding pixel regions PR may be along the horizontal direction (that is, the first direction DR1 and the second direction DR2. For example, the degree of misalignment of the microlenses 310 with respect to the corresponding pixel regions PR may be configured to increase from the center to the edge of the substrate region 100. The degree of misalignment of the microlenses 310 with respect to the corresponding pixel regions PR may be, for example, the distance between the centers of the corresponding microlenses 310 and the pixel regions PR in a planar view. The microlenses 310 may overlap corresponding pixel regions PR along the third direction DR3. As the corresponding microlenses 310 and the pixel regions PR are arranged to be offset from each other, an area in which the corresponding microlenses 310 and the pixel regions PR overlap each other along the third direction DR3 may decrease from the center of the substrate region 100 to the edge.

An additional layer 180 may be provided on the microlenses 310. The additional layer 180 may extend along the top surfaces of microlenses 310. The additional layer 180 may conformally cover the top surfaces of the microlenses 310. In some example embodiments, the additional layer 180 may include a top antireflective layer (TARL). For example, the additional layer 180 may be a transparent layer containing an organic material.

According to some example embodiments of the inventive concepts, the focus areas of incident light IL may be aligned with the sweet spots SP by the microlenses 310. Accordingly, the image sensor PA1 with improved photoelectric conversion efficiency can be provided.

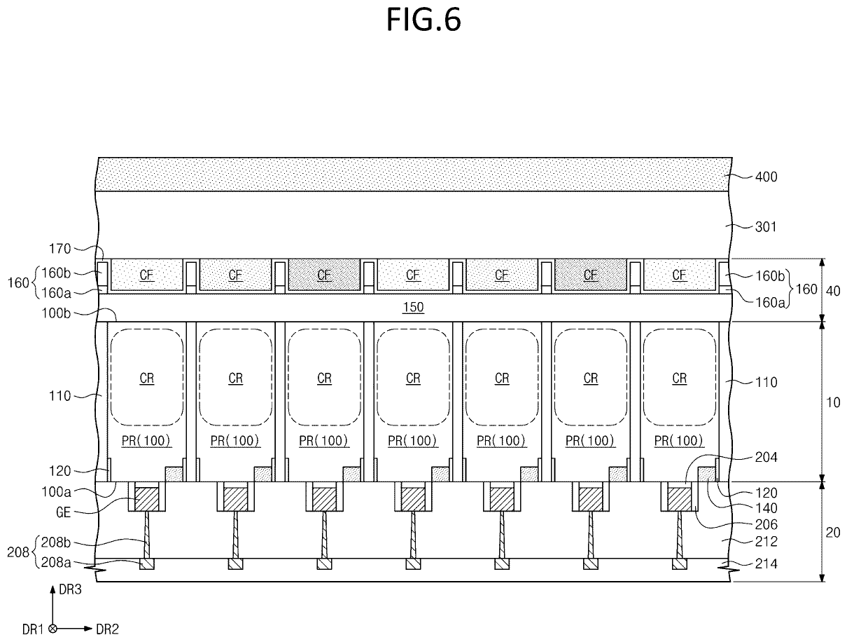

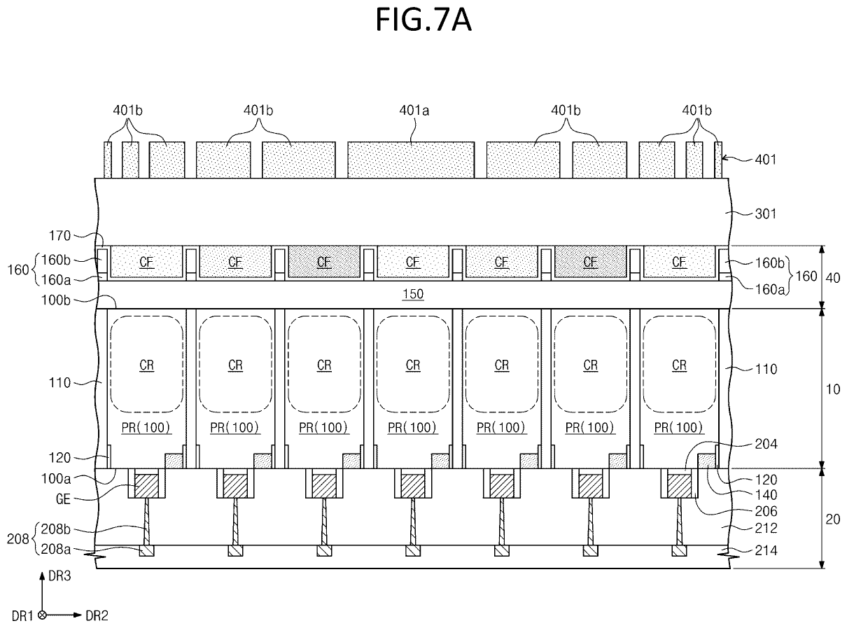

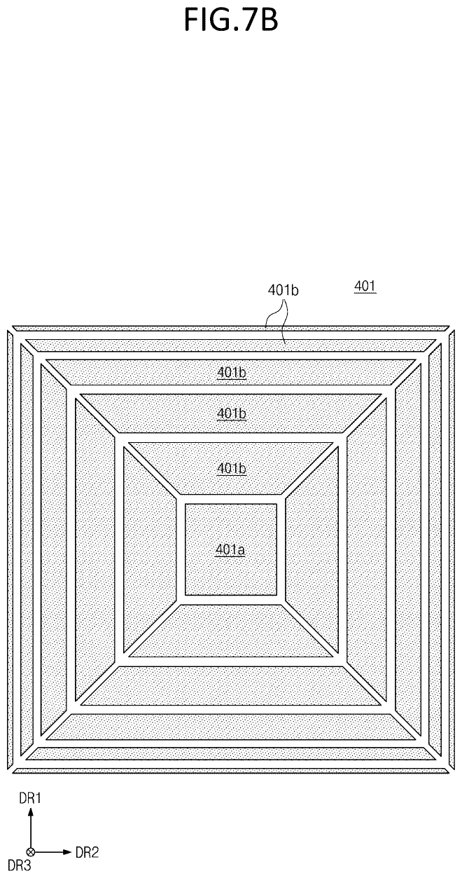

FIGS. 6, 7A, 8, 9, 10, 11, 12, 13, and 14 are cross-sectional views for explaining a method of manufacturing an image sensor according to some example embodiments. FIG. 7B is a plan view showing the preliminary sacrificial patterns of FIG. 7A. For brevity of explanation, details substantially the same as that described with reference to FIGS. 4 and 5 may not be described.

Referring to FIG. 6, a device layer 10, a wiring layer 20, and a color filter layer 40 may be formed. The device layer 10, the wiring layer 20, and color filter layer 40 may be substantially the same as the device layer 10, the wiring layer 20, and color filter layer 40 described with reference to FIGS. 4 and 5. A first preliminary lens layer 301 and a first sacrificial layer 400 may be sequentially formed on the color filter layer 40.

Forming the first preliminary lens layer 301 may include depositing a microlens material on the color filter layer 40. For example, the microlens materials include glass (e.g., silicon-based, chalcogenide-based), thermosetting resin (e.g., polycarbonate-based, polyester-based resin), and photocurable resin (e.g., acrylic resin, epoxy-based, polyurethane-based), or fluoride-based (CaF2) materials. Depositing the microlens material may be performed using, for example, a physical vapor deposition (PVD) process, a chemical vapor deposition (CVD) process, or an atomic layer deposition (ALD) process. The top surface of the first preliminary lens layer 301 may be formed to be substantially parallel to the back side 100b. For example, the top surface of the first preliminary lens layer 301 may extend along the first direction DR1 and the second direction DR2.

The first sacrificial layer 400 may be formed on the first preliminary lens layer 301. The first sacrificial layer 400 may include an organic material. For example, the first sacrificial layer 400 may include photoresist. In some example embodiments, the first sacrificial layer 400 may be formed by a coating process. The coating process may be performed, for example, using a spin coating method, a spray coating method, a dip coating method, an inkjet printing method, or a slot-die coating method. The top surface of the first sacrificial layer 400 may be formed to be substantially parallel to the top surface of the first preliminary lens layer 301. For example, the top surface of the first sacrificial layer 400 may extend along the first direction DR1 and the second direction DR2.

Referring to FIGS. 7A and 7B, the first sacrificial layer 400 may be patterned to form first preliminary sacrificial patterns 401. Patterning the first sacrificial layer 400 may include an exposure process that irradiates light to a required area of the first sacrificial layer 400 and a development process that removes either the exposed portion or the non-exposed portion. As shown in FIG. 7B, the first preliminary sacrificial patterns 401 may include a central pattern 401a and peripheral patterns 401b arranged radially from the central pattern 401a. The central pattern 401a and the peripheral patterns 401b may be spaced apart from each other. The shape of the first preliminary sacrificial patterns 401 may be determined as needed. The width of the peripheral patterns 401b may become smaller as the distance from the central pattern 401a increases. The width of the peripheral patterns 401b may be the size of the peripheral patterns 401b along the direction from the center of the substrate region 100 to the edge.

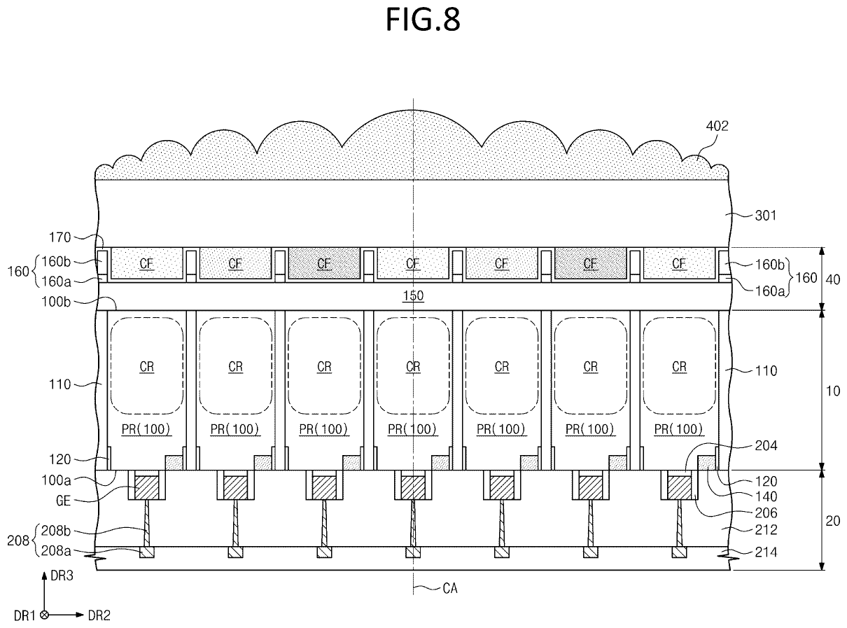

Referring to FIG. 8, the first preliminary sacrificial patterns 401 may be reflowed to form a second preliminary sacrificial layer 402. During the reflow process, the central pattern 401a and the peripheral patterns 401b may flow toward the top surface of the first preliminary microlens layer 301 while preserving the volume. Flowing portions of the first preliminary sacrificial patterns 401 may be provided in regions between the central pattern 401a and the peripheral patterns 401b. The second preliminary sacrificial layer 402 may include convex patterns with a rounded surface. The convex patterns that are immediately adjacent to each other may be connected to each other.

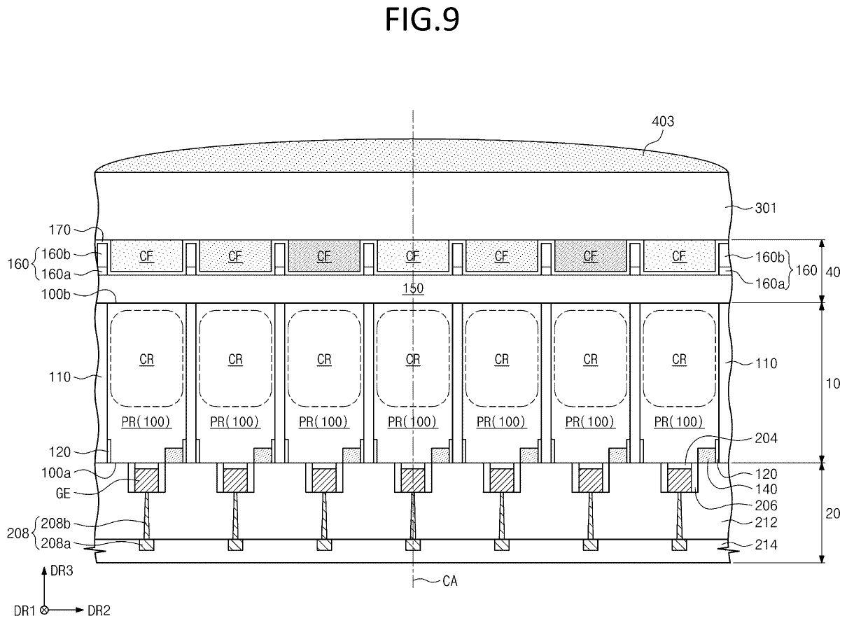

Referring to FIG. 9, the second preliminary sacrificial layer 402 may be reflowed to form a first sacrificial layer 403. During the reflow process, the second preliminary sacrificial layer 402 may flow toward the top surface of the first preliminary lens layer 301. The top surface of the first sacrificial layer 403 may be formed in a thermodynamically stable form. The top surface of the first sacrificial layer 403 may be configured to have a convex shape along the third direction DR3. The thickness of the first sacrificial layer 403 may decrease from the center to the edge of the first sacrificial layer 403.

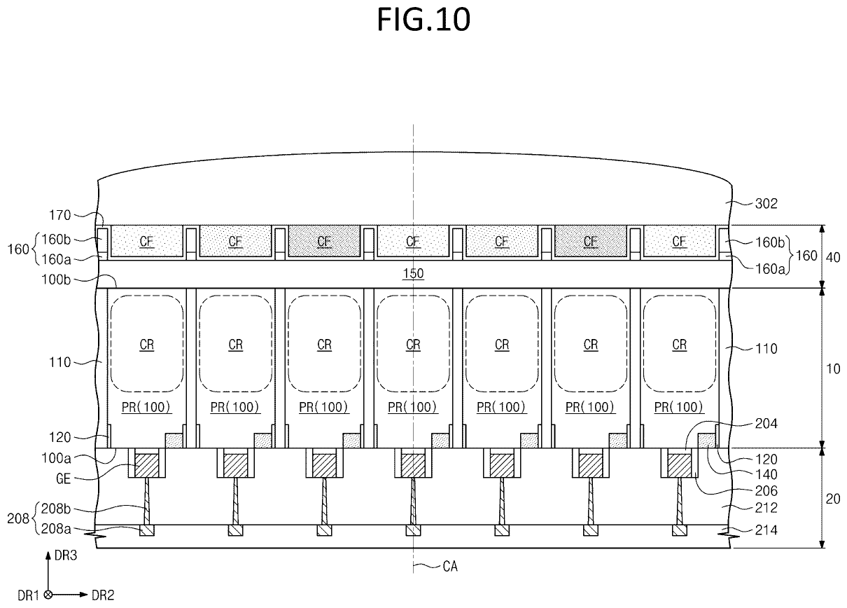

Referring to FIG. 10, the first preliminary lens layer 301 may be etched to form a second preliminary lens layer 302. Etching the first preliminary lens layer 301 may include, for example, an etch back process. During the etching process, the first preliminary lens layer 301 located positioned under the thin portion of the first sacrificial layer 403 may be etched earlier than the first preliminary lens layer 301 positioned under the thick portion of the first sacrificial layer 403. Accordingly, the second preliminary lens layer 302 may have a surface profile corresponding to the surface of the first sacrificial layer 403. In some example embodiments, etching the first preliminary lens layer 301 may be performed until the first sacrificial layer 403 is completely removed.

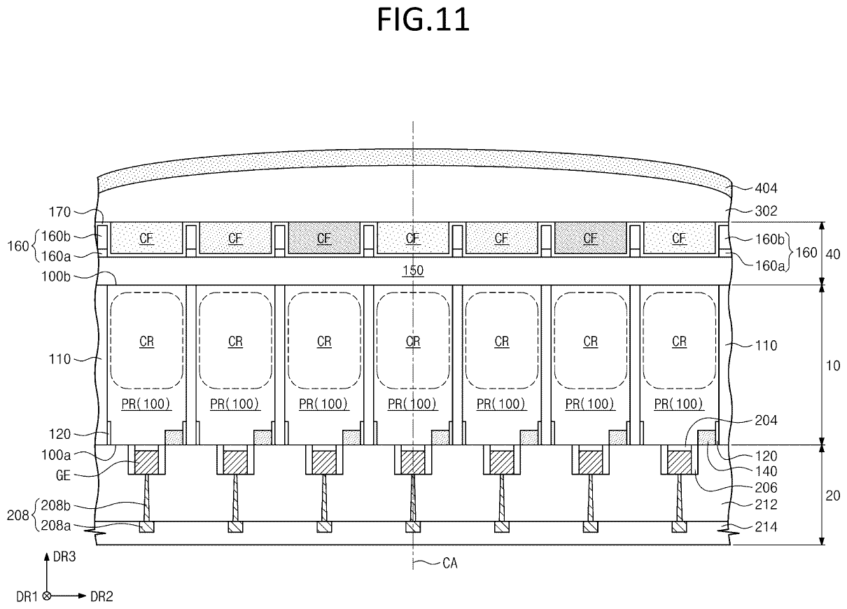

Referring to FIG. 11, a third preliminary sacrificial layer 404 may be formed on the second preliminary lens layer 302. The third preliminary sacrificial layer 404 may include an organic material. For example, the third preliminary sacrificial layer 404 may include photoresist. The third preliminary sacrificial layer 404 may be formed by a coating process. The coating process may be performed, for example, using a spin coating method, spray coating method, dip coating method, inkjet printing method, or slot-die coating method. The third preliminary sacrificial layer 404 may be formed along the top surface of the second preliminary lens layer 302.

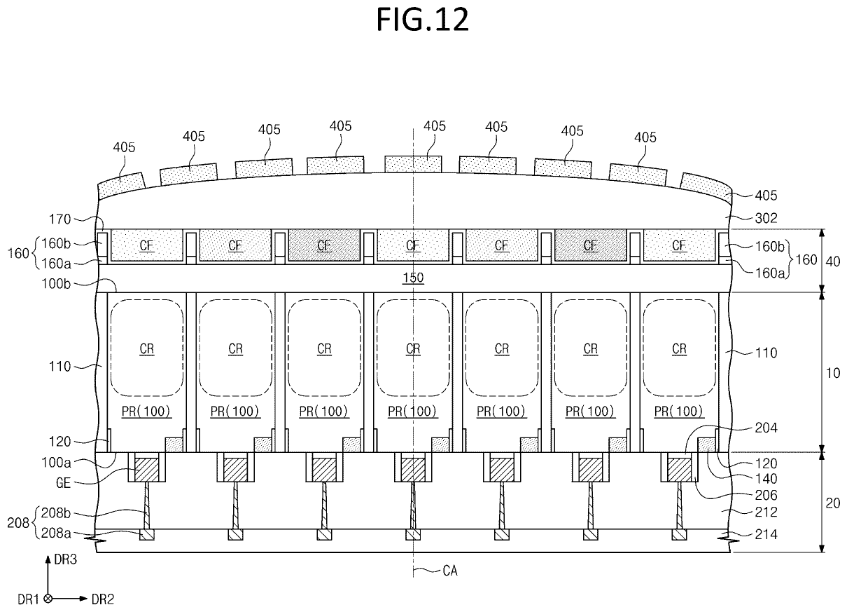

Referring to FIG. 12, the third preliminary sacrificial layer 404 may be patterned to form second preliminary sacrificial patterns 405. Patterning the third preliminary sacrificial layer 404 may include an exposure process that irradiates light to a required area of the third preliminary sacrificial layer 404 and a development process that removes either the exposed portion or the non-exposed portion. The second preliminary sacrificial patterns 405 may be spaced apart from each other. From a planar view, the second preliminary sacrificial patterns 405 may have a square shape. The second preliminary sacrificial patterns 405 may be arranged along the top surface of the second preliminary lens layer 302. The second preliminary sacrificial patterns 405 may have substantially the same thickness.

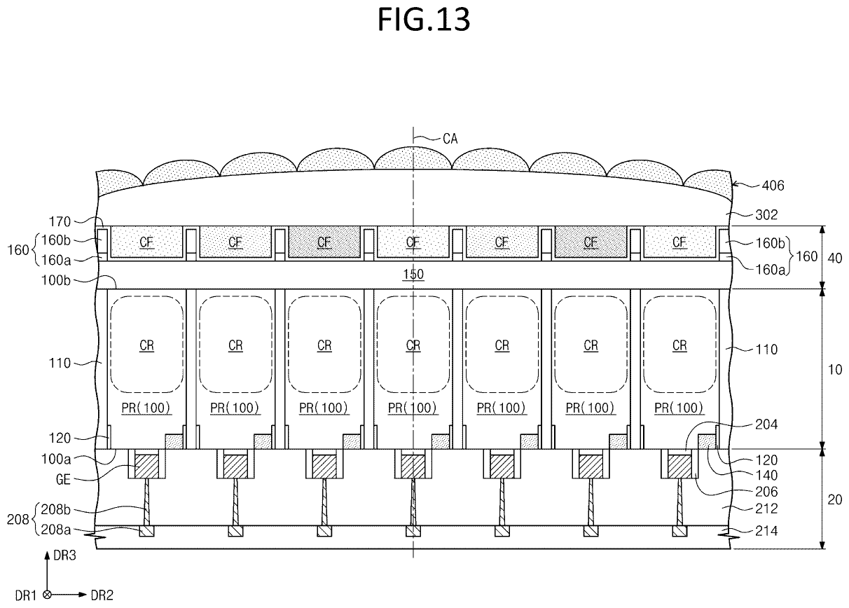

Referring to FIG. 13, the second preliminary sacrificial patterns 405 may be reflowed to form a second sacrificial layer 406. During the reflow process, the second preliminary sacrificial patterns 405 may flow toward the top surface of the second preliminary lens layer 302 while preserving their respective volumes. Flowing portions of the second preliminary sacrificial patterns 405 may be provided in regions between the second preliminary sacrificial patterns 405. The second sacrificial layer 406 may include convex patterns with a rounded surface. The convex patterns that are immediately adjacent to each other may be connected to each other. The convex patterns with rounded surfaces may be configured so that the microlenses 310 have the required radius of curvature. For example, a heating process may be performed on the convex patterns to adjust the surface curvature of the convex patterns.

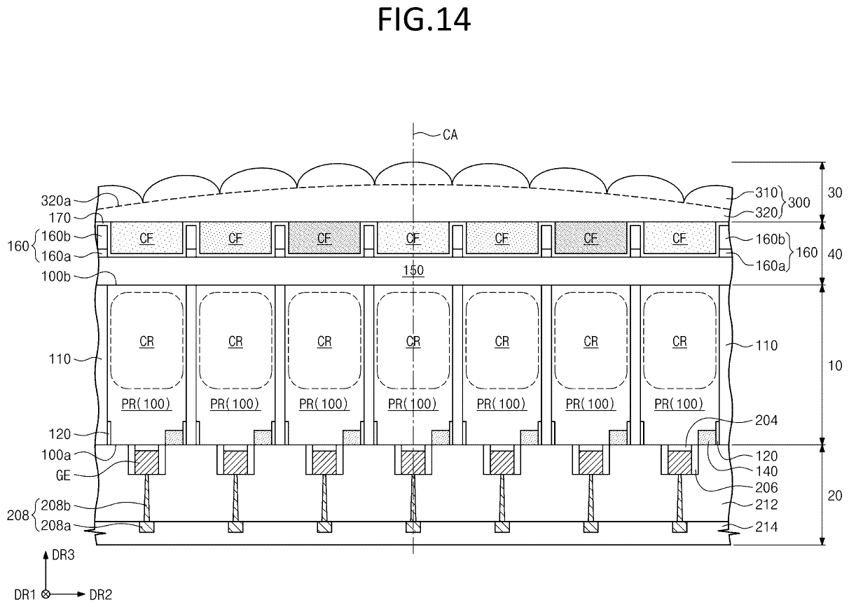

Referring to FIG. 14, the second preliminary lens layer 302 may be etched to form the microlens array layer 300. Etching the second preliminary lens layer 302 may include, for example, an etch back process. During the etching process, the second preliminary lens layer 302 positioned under the thin portion of the second sacrificial layer 406 may be etched earlier than the second preliminary lens layer 302 positioned under the thick portion of the second sacrificial layer 406. Accordingly, the second preliminary lens layer 302 may have a surface profile corresponding to the second sacrificial layer 406. In some example embodiments, etching the second preliminary lens layer 302 may be performed until the second sacrificial layer 406 is completely removed. Accordingly, the microlenses 310 may be formed. A portion of the second preliminary microlens array layer 300 that is not etched may be the supporting portion 320. The microlenses 310 may be formed to match the positions of the focus area of incident light IL to the sweet spots SP.

Referring to FIGS. 4 and 5, the additional layer 180 may be formed on the microlenses 310. Forming the additional layer 180 may be performed using, for example, a physical vapor deposition (PVD) process, a chemical vapor deposition (CVD) process, or an atomic layer deposition (ALD) process. The additional layer 180 may extend along the top surface of microlenses 310. The additional layer 180 may be formed to conformally cover the top surface of the microlenses 310. In some example embodiments, the additional layer 180 may include the top antireflective layer (TARL). For example, the additional layer 180 may be a transparent layer containing the organic material.

According to some example embodiments of the inventive concepts, the focus areas of incident light IL may be aligned with the corresponding sweet spots SP by the microlenses 310, respectively. Accordingly, the image sensor PA1 with improved photoelectric conversion efficiency may be formed.

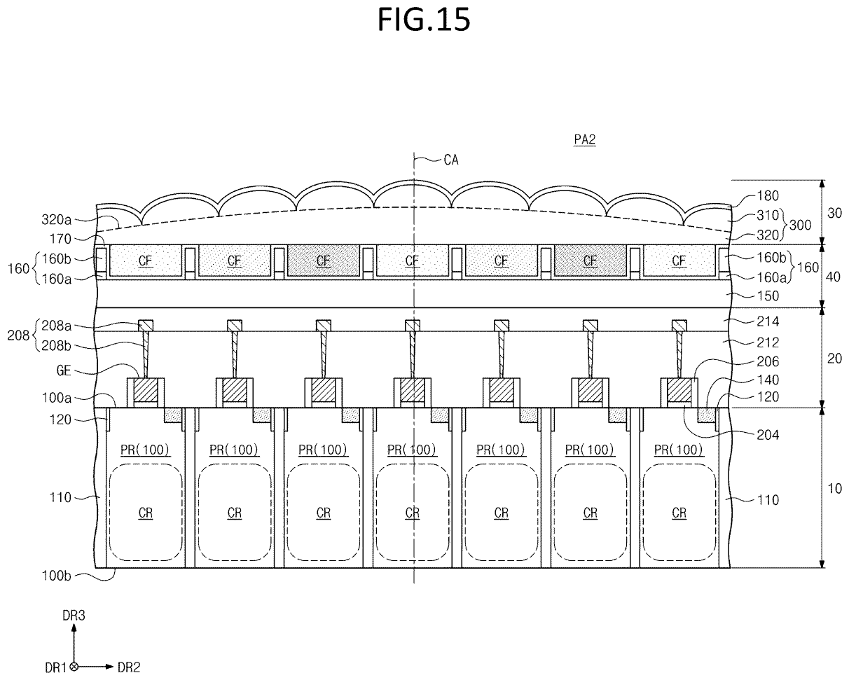

FIG. 15 is a cross-sectional view showing an image sensor according to some example embodiments. For brevity of explanation, differences from those described with reference to FIGS. 4 and 5 are explained.

Referring to FIG. 15, a front-side illuminated image sensor PA2 may be provided. The image sensor PA2 may include a device layer 10, a wiring layer 20, a color filter layer 40, and a lens layer 30. Unlike those described with reference to FIGS. 4 and 5, the wiring layer 20 may be provided between the device layer 10 and the color filter layer 40. The wiring layer 20, the color filter layer 40, and the lens layer 30 may be sequentially provided on the front side 100a of the substrate region 100. Incident light IL may pass through the front side 100a and enter the photoelectric conversion region CR.

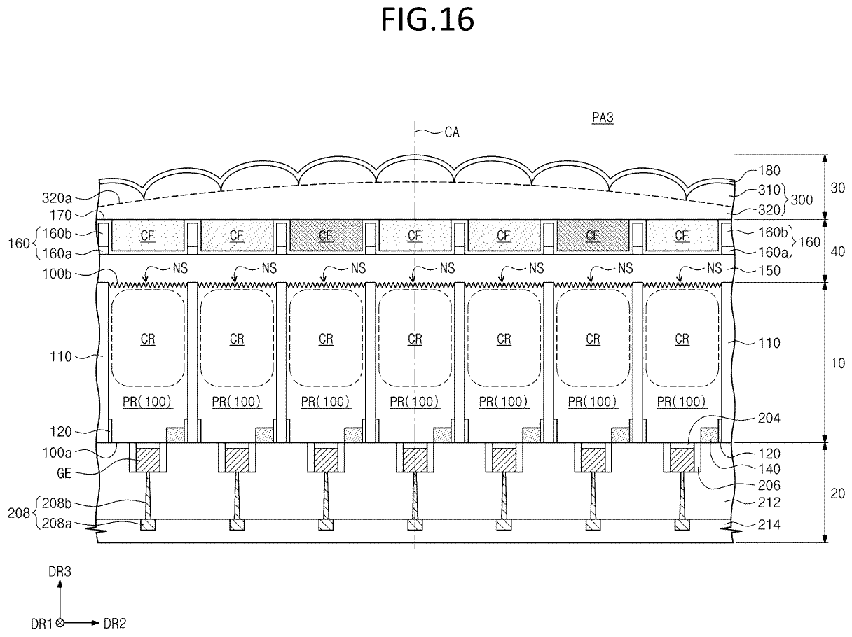

FIG. 16 is a cross-sectional view showing an image sensor according to some example embodiments. For brevity of explanation, differences from those described with reference to FIGS. 4 and 5 are explained.

Referring to FIG. 16, an image sensor PA3 may be provided. The image sensor PA3 may include a device layer 10, a wiring layer 20, a color filter layer 40, and a lens layer 30. Unlike those described with reference to FIGS. 4 and 5, nanostructures NS may be provided on the back side 100b of the substrate region 100. The nanostructures NS may be formed adjacent to the bottom surface of the bottom insulating layer 150. For example, the nanostructures NS may be at least one of a tip, a cone, a dome, a wire, and a pillar. For example, the nanostructures NS may be formed by performing the etching process on the back side 100b of the substrate region 100. The nanostructures NS can be configured to improve antireflection function. For example, the nanostructures NS may be configured so that incident light IL reflected from the top and bottom surfaces of the bottom insulating layer 150 causes destructive interference.

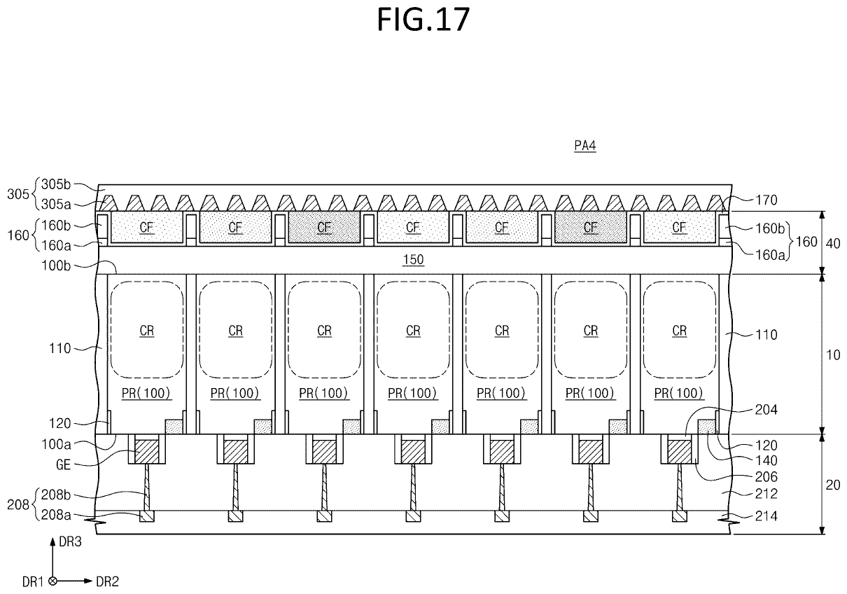

FIG. 17 is a cross-sectional view showing an image sensor according to some example embodiments. For brevity of explanation, differences from those described with reference to FIGS. 4 and 5 are explained.

Referring to FIG. 17, unlike those described with reference to FIGS. 4 and 5, a nanoprism layer 305 may be provided on the color filters CF. The nanoprism layer 305 may include nanoprism patterns 305a and an insulating layer 305b covering the nanoprism patterns 305a. The nanoprism patterns 305a may be configured to absorb and scatter incident light IL using localized surface plasmon resonance. The nanoprism layer 305 may be configured to focus incident light IL on the photoelectric conversion region CR. For example, the nanoprism layer 305 may include a dielectric material (e.g., titanium dioxide (TiO₂)) and a metal (e.g., silver (Ag), gold (Au), and a combination thereof). The shape of the nanoprism layer 305 may be determined as needed. For example, the nanoprism layer 305 may have a triangular or hexagonal shape.

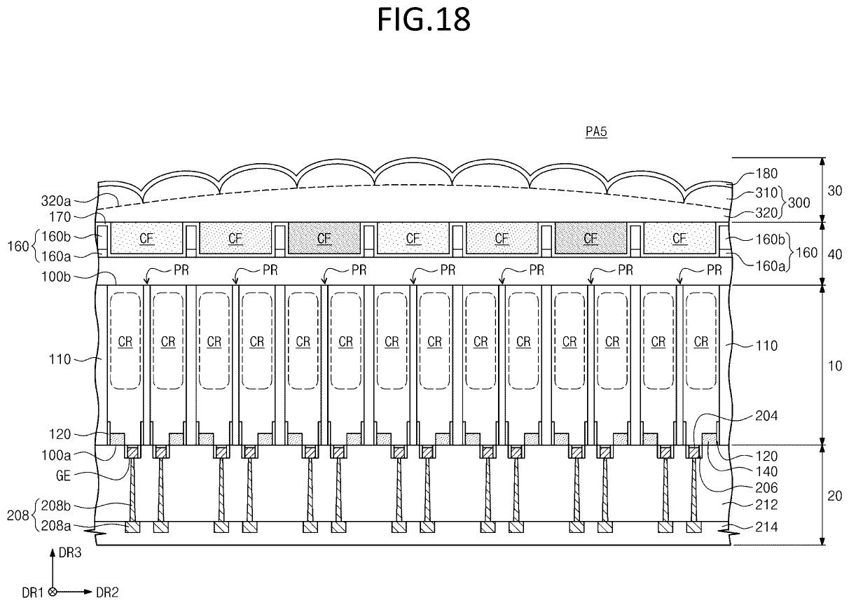

FIG. 18 is a cross-sectional view showing an image sensor according to some example embodiments. For brevity of explanation, differences from those described with reference to FIGS. 4 and 5 are explained. Referring to FIG. 18, unlike those described with reference to FIGS. 4 and 5, a pair of photoelectric conversion regions CR may be formed in one pixel region PR. The isolation layer 110 is provided between the pair of photoelectric conversion regions CR to prevent, limit or reduce crosstalk. The floating diffusion regions 140, the gate electrodes GE, and the wires 208 may be provided corresponding to each of the photoelectric conversion regions CR. Each of the microlenses 310 may correspond to the pair of photoelectric conversion regions CR. For example, incident light IL passing through the microlenses 310 may be focused on one of the corresponding pair of photoelectric conversion regions CR. Each of the pair of photoelectric conversion regions CR may include the sweet spot. The microlenses 310 may be configured to match the focus areas of incident light IL to the sweet spots SP. The image sensor PA5 may extract a phase difference between incident light IL incident on one side of the photoelectric conversion regions CR and incident light IL incident on the other side of the photoelectric conversion regions CR among a pair of photoelectric conversion regions CR provided in one pixel regions PR. The phase difference of incident light IL incident on the field CR can be extracted. In some example embodiments, a camera, a smartphone, or the like including the image sensor PA1 may perform auto-focusing using the phase difference of incident light IL.

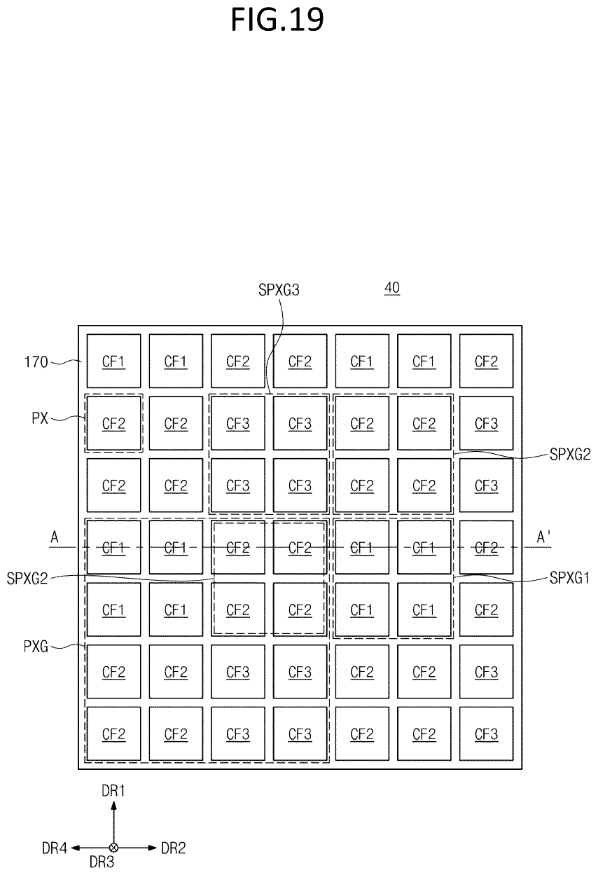

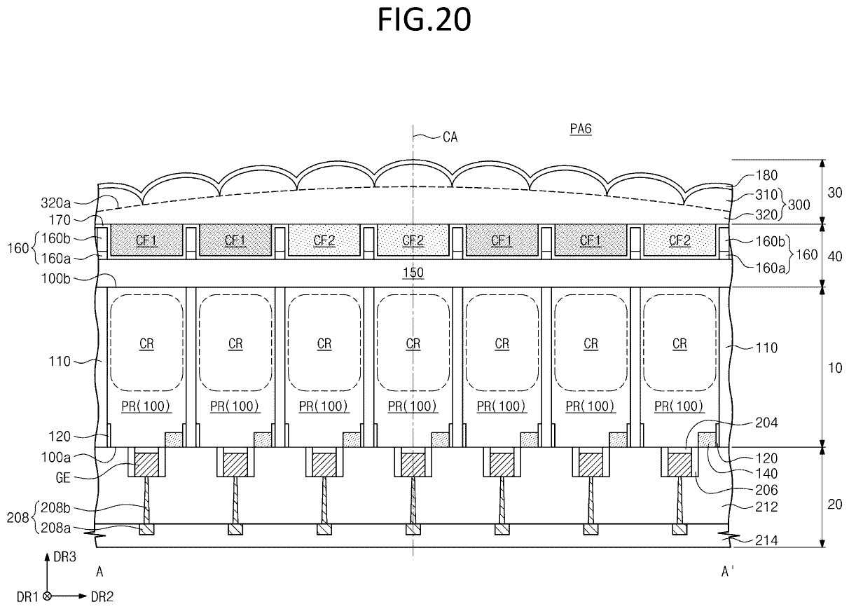

FIG. 19 is a plan view showing the color filter layer 40 according to some example embodiments. FIG. 20 is a cross-sectional view of an image sensor PA6 along line A-A′ of FIG. 19. For brevity of explanation, differences from those described with reference to FIG. 2 and differences from those described with reference to FIGS. 4 and 5 are explained.

Referring to FIG. 19, a pixel group PXG may include four sub-pixel groups SPXG1, SPXG2, and SPXG3 arranged in a 2×2 array. The four sub-pixel groups SPXG1, SPXG2, SPXG3 may include a first sub-pixel group SPXG1, a pair of second sub-pixel groups SPXG2, and a third sub-pixel group SPXG3. For example, the pair of second sub-pixel groups SPXG2 may be provided along a diagonal direction (e.g., a direction between the first direction DR1 and the second direction DR2). For example, the pair of second sub-pixel groups SPXG2 may be provided along a diagonal direction (e.g., a direction between the first direction DR1 and the fourth direction DR4). The first and third sub-pixel groups SPXG1 and SPXG3 may be provided in a region where the pair of second sub-pixel groups SPXG2 are not located among the pixel groups PXG. In some other example embodiments, the four sub-pixel groups SPXG1, SPXG2, and SPXG3 may include a pair of the first sub-pixel group SPXG1, the second sub-pixel group SPXG2, and the third sub-pixel group SPXG3. For example, the pair of first sub-pixel groups SPXG1 may be provided along the diagonal direction (e.g., the direction between the first direction DR1 and the second direction DR2). For example, the pair of first sub-pixel groups SPXG1 may be provided along the diagonal direction (e.g., the direction between the first direction DR1 and the fourth direction DR4). The second and third sub-pixel groups SPXG2 and SPXG3 may be provided in a region where the pair of first sub-pixel groups SPXG1 are not located among the pixel groups PXG. In some other example embodiments, the four sub-pixel groups SPXG1, SPXG2, and SPXG3 may include the first sub-pixel group SPXG1, the second sub-pixel group SPXG2, and a pair of the third sub-pixel group SPXG3. For example, the third sub-pixel groups SPXG3 may be provided along the diagonal direction (e.g., the direction between the first direction DR1 and the second direction DR2). For example, the pair of third sub-pixel groups SPXG3 may be provided along the diagonal direction (e.g., the direction between the first direction DR1 and the fourth direction DR4). The first and second sub-pixel groups SPXG1 and SPXG2 may be provided in a region where the pair of third sub-pixel groups SPXG3 are not located among the pixel groups PXG. Each of the four sub-pixel groups SPXG1, SPXG2, SPXG3 may include four pixels PX arranged in the 2×2 array. For example, each of the four sub-pixel groups SPXG1, SPXG2, and SPXG3 may include four pixels PX corresponding to substantially the same color. The four pixels PX included in each of the four sub-pixel groups SPXG1, SPXG2, and SPXG3 may be immediately adjacent to each other to form a tetra cell structure. Unlike the one shown in FIG. 2, the pixel group PXG may include sixteen pixels PX. In some other example embodiments, each of the four sub-pixel groups SPXG1, SPXG2, and SPXG3 may include nine pixels PX. The four pixels PX included in each of the four sub-pixel groups SPXG1, SPXG2, and SPXG3 may include the same color filters. The four pixels PX belonging to the first sub-pixel group SPXG1 may include first color filters CF1. For example, the first color filters CF1 may be configured to transmit red light. Each of the four pixels PX belonging to the second sub-pixel group SPXG2 may include second color filters CF2. For example, the second color filters CF2 may be configured to transmit green light. Each of the four pixels PX belonging to the third sub-pixel group SPXG3 may include third color filters CF3. For example, the third color filters CF3 may be configured to transmit blue light. From a planar view, each of the first color filters CF1, the second color filters CF2, and the third color filters CF3 may be arranged in the 2×2 array.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

The above description of some example embodiments of the inventive concepts provides examples for explaining the technical idea of the present disclosure. Therefore, the inventive concepts are not limited to the above some example embodiments. Within the technical idea of the present disclosure, various modifications and changes are possible, such as combining the above some example embodiments by those skilled in the art.

According to the present disclosure, an image sensor with improved photoelectric conversion efficiency may be provided.

According to the present disclosure, a method for fabricating an image sensor with improved photoelectric conversion efficiency.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. An image sensor comprising:
a substrate region including a first pixel region and a second pixel region; and
a microlens array layer on the substrate region, the microlens array layer including a first microlens and a second microlens respectively corresponding to the first pixel region and the second pixel region,
wherein the first pixel region and the second pixel region are respectively adjacent to a center and an edge of the microlens array layer,
wherein the first microlens is offset from the first pixel region and has a first inclination,
wherein the second microlens is offset from the second pixel region and has a second inclination greater than the first inclination, and
wherein a degree to which the first and second microlenses are offset from the first and second pixel regions, and the first and second inclinations, are based on an incident angle of incident light to the first and second microlenses.

2. The image sensor of claim 1, wherein, from a planar view, a distance between a center of the second microlens and a center of the second pixel region is greater than a distance between a center of the first microlens and a center of the first pixel region.

3. The image sensor of claim 2, wherein, from a planar view, the distance between the center of the second microlens and the center of the second pixel region, and the distance between the center of the first microlens and the center of the first pixel region are based on the incident angle.

4. The image sensor of claim 1, wherein, from a planar view, the first and second microlenses are configured to respectively overlap the first and the second pixel regions, and
an area of a region that the second microlens and the second pixel region overlap each other is smaller than an area of a region that the first microlens and the first pixel region overlap each other.

5. The image sensor of claim 4, wherein the region that the second microlens and the second pixel region overlap each other has a smaller width along a direction from the center to the edge of the microlens array layer than the region that the first microlens and the first pixel region overlap each other.

6. The image sensor of claim 1, wherein the first pixel region and the second pixel region respectively include a first sweet spot and a second sweet spot with relatively high photoelectric conversion efficiency, and
wherein the first microlens and the second microlens are respectively configured to focus the incident light on the first sweet spot of the first pixel region and the second sweet spot of the second pixel region.

7. The image sensor of claim 1, wherein a height of the second microlens from a surface of the substrate region is less than a height of the first microlens from the surface of the substrate region.

8. The image sensor of claim 1, wherein the microlens array layer further includes a supporting portion between the first and second microlenses and the substrate region,
wherein the supporting portion has a thickness that decreases from the center to the edge of the microlens array layer, and
wherein the first and second microlenses are on a top surface of the supporting portion.

9. The image sensor of claim 8, wherein the top surface of the supporting portion has an inclination that increases from the center to the edge of the microlens array layer, and
wherein the inclination is based on the incident angle.

10. The image sensor of claim 1, further comprising:
a first color filter and a second color filter between the microlens array layer and the substrate region, the first and second color filters respectively corresponding to the first and second microlenses, and
wherein the first and second microlenses are respectively offset from the first and second color filters based on the incident angle of the incident light.

11. The image sensor of claim 1, wherein the first and second microlenses are configured to focus the incident light on respective same positions within the first and second pixel regions.

12. The image sensor of claim 1, wherein the first and second pixel regions are immediately adjacent to each other, and
wherein, from a planar view, the second microlens overlaps the second pixel region and the first pixel region.

13. The image sensor of claim 1, wherein each of the first and second pixel regions include one photoelectric conversion region or a pair of photoelectric conversion regions.

14. The image sensor of claim 1, further comprising:
a plurality of transistors electrically connected to the first and second pixel regions,
wherein the plurality of transistors are on opposite sides of the microlens array layer with respect to the substrate region, or the plurality of transistors are between the substrate region and the microlens array layer.

15. A method for manufacturing an image sensor comprising:
forming a first preliminary lens layer on a substrate region including a plurality of pixel regions;
forming a first sacrificial layer on the first preliminary lens layer, the first sacrificial layer having a thickness that decreases toward an edge of the first sacrificial layer;
forming a second preliminary lens layer by performing an etch-back process on the first sacrificial layer and the first preliminary lens layer, the second preliminary lens layer having a thickness that decreases toward an edge of the second preliminary lens layer;
forming a plurality of first preliminary sacrificial patterns on the second preliminary lens layer;
forming a second sacrificial layer by performing a reflow process on the plurality of first preliminary sacrificial patterns; and
forming a microlens array layer by performing an etch-back process on the second sacrificial layer and the second preliminary lens layer,
wherein, from a planar view, the plurality of first preliminary sacrificial patterns are offset from the plurality of pixel regions immediately adjacent thereto.

16. The method for manufacturing the image sensor of claim 15, wherein the forming of the first sacrificial layer includes:
forming a first preliminary sacrificial layer on the first preliminary lens layer;
forming a plurality of second preliminary sacrificial patterns spaced apart from each other by patterning the first preliminary sacrificial layer;
forming a second preliminary sacrificial layer including a plurality of convex patterns connected to each other by performing a reflow process on the plurality of second preliminary sacrificial patterns; and
performing a reflow process on the second preliminary sacrificial layer.

17. The method for manufacturing the image sensor of claim 16, wherein the plurality of second preliminary sacrificial patterns include a central pattern and a plurality of peripheral patterns arranged radially from the central pattern, and
wherein the central pattern and the plurality of peripheral patterns are spaced apart from each other.

18. The method for manufacturing the image sensor of claim 17, wherein a width of the plurality of peripheral patterns along a direction from a center of the substrate region becomes smaller as a distance from the central pattern increases.

19. An image sensor comprising:
a substrate region including a plurality of pixel regions; and
a microlens array layer on the substrate region, the microlens array layer including a plurality of microlenses corresponding to the plurality of pixel regions, and the microlens array layer including a supporting portion between the plurality of microlenses and the substrate region,
wherein a top surface of the supporting portion has an inclination that increases from a center to an edge of the microlens array layer, and
wherein the plurality of microlenses are arranged along the top surface of the supporting portion and are offset from the plurality of pixel regions corresponding thereto based on an incidence angle of incident light to the plurality of microlenses.

20. The image sensor of claim 19, wherein a height of the plurality of microlenses from a surface of the substrate region decreases from a center of the microlens array layer to an edge of the microlens array layer.
